(19) United States
(12) Patent Application Publication
(10) Pub. No.: US 2021/0183953 A1
(43) Pub. Date: Jun. 17, 2021

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Wenjing YU, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/331,140

(22) PCT Filed: Feb. 18, 2019
(86) PCT No.: PCT/CN2019/075349

§ 371 Date: Mar. 7, 2019

(30) Foreign Application Priority Data
Sep. 26, 2018 (CN) 201811123193.4

(51) Int. Cl. H01L 27/32; H01L 51/52

(52) U.S. Cl. CPC H01L 27/322; H01L 51/5275; H01L 51/5253

(57) ABSTRACT

A display panel and a display device are provided. The display panel includes a substrate, a plurality of display elements, a thin film encapsulation layer, and a color film layer which are sequentially disposed. The color film layer includes a plurality of color filter units corresponding the display elements, respectively, and a plurality of black photoresists disposed within gaps between the adjacent color filter units. A protective layer is disposed between the thin film encapsulation layer and the color film layer.

### FIELD OF INVENTION

The present disclosure relates to a display technology field, and in particular, to a display panel and a display device.

### BACKGROUND OF INVENTION

A screen of a mobile device has high reflectivity to light when using the mobile device in an environment with high light intensity, resulting in lower contrast of the mobile device. In order to improve the contrast of the mobile device, a polarizer (POL) is attached to a top of the screen.

An absorption rate of light emitted by a display panel can reach 55% when a polarizer of the display panel absorbs external light, thereby reducing the luminous efficacy of the display panel. An existing method is to replace the polarizer with a color film layer, wherein the color film layer includes a red filter unit, a green filter unit, and a blue filter unit disposed corresponding to pixel positions. Black photoresists are disposed between two filter units of the red filter unit, the green filter unit, and the blue filter unit, so that the light emitted by an organic light emitting diode (OLED) layer is emitted through the filter units.

The existing method is to vaporize the filter units and photoresist materials directly on a surface of an encapsulation layer of the display panel. However, it will cause an organic solvent to be miscible with an organic layer in the encapsulation layer, thereby destroying a structure of the encapsulation layer and affecting the luminescence performance of the OLED layer. As a result, it is necessary to provide a display panel and a display device to solve the problems existing in the conventional technologies, as described above.

### SUMMARY OF THE INVENTION

An object of the present disclosure is to provide a display panel and a display device, which solve a problem that the organic solvent in an existing color film layer process causes erosion of a thin film encapsulation layer, thereby causing damage to the structure of the display panel.

To achieve the above objects, the present disclosure provides a display panel, the display panel includes a substrate, a plurality of display elements, a thin film encapsulation layer, a color film layer, and a protective layer, wherein the display elements are disposed on the substrate and comprising a first display unit, a second display unit, and a third display unit; the thin film encapsulation layer is disposed on the display elements; the color film layer is disposed on the thin film encapsulation layer and includes a plurality of color filter units corresponding the display elements, respectively and a plurality of black photoresists are disposed within gaps between adjacent color filter units; the protective layer is disposed between the thin film encapsulation layer and the color film layer and configured to protect the thin film encapsulation layer from erosion during a color film layer forming process; the first display unit, the second display unit, and the third display unit are one of a red sub-pixel, a green sub-pixel, and a blue sub-pixel, and a sub-pixel color of the first display unit, the second display unit, and the third display unit are different.

In one embodiment of the present disclosure, two ends of the thin film encapsulation layer contact the substrate, and the protective layer covers a boundary of the thin film encapsulation layer and contacts the substrate.

In one embodiment of the present disclosure, a preparation material of the protective layer is an inorganic material.

In one embodiment of the present disclosure, the inorganic material is a nano inorganic material.

In one embodiment of the present disclosure, the protective layer is prepared by adopting a transparent metal material.

In one embodiment of the present disclosure, a refractive index of the protective layer is greater than a refractive index of the thin film encapsulation layer.

In one embodiment of the present disclosure, the protective layer comprises at least one first sub-film layer and at least one second sub-film layer stacked on each other, and the first sub-film layer and the second sub-film layer are made of different materials.

In one embodiment of the present disclosure, the first sub-film layer and the second sub-film layer are prepared by adopting an inorganic material.

In one embodiment of the present disclosure, the first sub-film layer is prepared by adopting an inorganic material, and the second sub-film layer is prepared by adopting an organic material.

To achieve the above objects, the present disclosure provides a display device, and the display device includes a display panel and a frame, wherein the display panel includes a substrate, a plurality of display elements, a thin film encapsulation layer, a color film layer, and a protective layer, wherein the display elements are disposed on the substrate; the thin film encapsulation layer is disposed on the display elements; the color film layer is disposed on the thin film encapsulation layer and comprises a plurality of color filter units corresponding the display elements, respectively and a plurality of black photoresists is disposed within gaps between adjacent color filter units; the protective layer is disposed between the thin film encapsulation layer and the color film layer and configured to protect the thin film encapsulation layer from erosion during a color film layer forming process.

To achieve the above objects, the present disclosure provides a display panel, the display panel includes a substrate, a plurality of display elements, a thin film encapsulation layer, a color film layer, and a protective layer, wherein the display elements are disposed on the substrate; the thin film encapsulation layer is disposed on the display elements; the color film layer is disposed on the thin film encapsulation layer and comprises a plurality of color filter units corresponding the display elements, respectively and a plurality of black photoresists are disposed within gaps between adjacent color filter units; the protective layer is disposed between the thin film encapsulation layer and the color film layer and configured to protect the thin film encapsulation layer from erosion during a color film layer forming process.

In one embodiment of the present disclosure, two ends of the thin film encapsulation layer contact the substrate, and the protective layer covers a boundary of the thin film encapsulation layer and contacts the substrate.

In one embodiment of the present disclosure, a preparation material of the protective layer is an inorganic material.

In one embodiment of the present disclosure, the inorganic material is a nano-inorganic material.

In one embodiment of the present disclosure, the protective layer is prepared by adopting a transparent metal material.

In one embodiment of the present disclosure, a refractive index of the protective layer is greater than a refractive index of the thin film encapsulation layer.

In one embodiment of the present disclosure, the protective layer comprises at least one first sub-film layer and at least one second sub-film layer stacked on each other, and the first sub-film layer and the second sub-film layer are made of different materials.

In one embodiment of the present disclosure, the first sub-film layer and the second sub-film layer are prepared by adopting an inorganic material.

In one embodiment of the present disclosure, the first sub-film layer is prepared by adopting an inorganic material, and the second sub-film layer is prepared by adopting an organic material.

In one embodiment of the present disclosure, a refractive index of the protective layer is greater than a refractive index of the thin film encapsulation layer.

As described above, the present disclosure provides a protective layer between the thin film encapsulation layer and the color film layer. In the color film layer forming process, the organic solvent is prevented from eroding the film encapsulation layer, thereby improving the stability of the display panel.

### DESCRIPTION OF DRAWINGS

In order to more clearly illustrate the embodiments or the prior art technical solutions embodiment of the present disclosure, will implement the following figures for the cases described in the prior art or require the use of a simple introduction. Obviously, the following description of the drawings are only some of those of ordinary skill in terms of creative effort without precondition, you can also obtain other drawings based on these drawings embodiments of the present disclosure.

FIG. 1 is a schematic structural view of a display panel according to an embodiment of the present disclosure.

FIG. 2 is a schematic structural view of a protective layer according to an embodiment of the present disclosure.

### DETAILED DESCRIPTION OF THE PREFERRED EMBODIMENTS

The structure and the technical means adopted by the present disclosure to achieve the above and other objects can be best understood by referring to the following detailed description of the preferred embodiments and the accompanying drawings. Furthermore, directional terms described by the present disclosure, such as upper, lower, front, back, left, right, inner, outer, side, longitudinal/vertical, transverse/horizontal, etc., are only directions by referring to the accompanying drawings, and thus the used directional terms are used to describe and understand the present disclosure, but the present disclosure is not limited thereto.

The present disclosure provides a display panel and a display device. In an existing color film layer process, an organic solvent causes erosion of a thin film encapsulation layer, causing damage to a structure of the display panel, and this embodiment can improve the defect.

The present disclosure is further described below in conjunction with the accompanying drawings and specific embodiments.

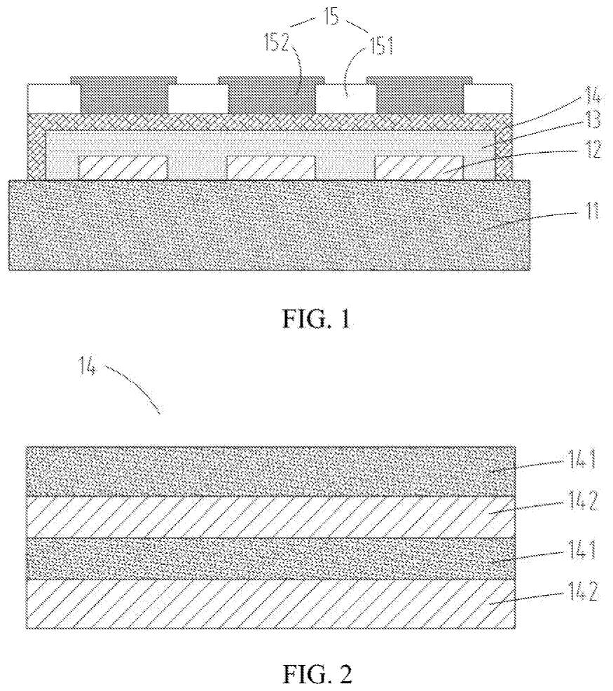

Referring to FIG. 1, a schematic structural view of a display panel according to an embodiment of the present disclosure is illustrated.

The display panel includes a substrate 11 and a plurality of display elements 12, wherein material of the substrate 11 can be one of a glass substrate, a quartz substrate, and a resin substrate. The display elements 12 are disposed on the substrate 11. The display element 12 includes a first display unit, a second display unit, and a third display unit.

In one embodiment, each of the display elements 12 is one of a red sub-pixel, a green sub-pixel, and a blue sub-pixel. The first display unit, the second display unit, and the third display unit are one of a red sub-pixel, a green sub-pixel, and a blue sub-pixel, and colors of sub-pixels of the first display unit, the second display unit, and the third display unit are different.

Each of the display elements 12 includes an organic light emitting diode (OLED) film layer, and the OLED film layer includes an anode layer, a pixel defining layer, a first common layer, a light emitting layer, a second common layer, and a cathode layer.

In one embodiment, the light emitting layer is an organic semiconductor and has a special energy band structure. Electrons generated by the cathode and holes generated by the anode meet in the light emitting layer. Photons enter our eyes and are the colors we see. As a light source of the display panel, the light of different colors is generated by sub-pixels of different colors.

The display panel further includes a thin film encapsulation layer 13 disposed on the display elements 12, and the thin film encapsulation layer 13 is configured to prevent external water and oxygen from invading and corroding an organic light emitting layer in the display elements 12. The thin film encapsulation layer 13 includes organic encapsulation layers and inorganic encapsulation layers which are alternately laminated.

In one embodiment, the organic encapsulation layers are located in the middle of the thin film encapsulation layer 13, and the inorganic encapsulation layers are located on two sides of the thin film encapsulation layer 13, thereby wrapping the organic encapsulation layers in the middle.

Although the organic encapsulation layers are very flexible, the ability to block water and oxygen is very limited. The inorganic encapsulation layers have the capacity to block water and oxygen. However, it is difficult to prepare a dense high-quality film layer when reaching a certain thickness, and the performance of the film is a rigid structure and easily broken. Therefore, most of the current flexible encapsulation materials are based on an encapsulation structure of alternating composite of organic and inorganic multilayer films.

The display panel further includes a color film layer 15 disposed on the thin film encapsulation layer 13. The color film layer 15 includes a plurality of color filter units 152 corresponding the display elements 12, respectively, and a plurality of black photoresists 151 disposed within gaps between the adjacent color filter units 152.

The color film layer 15 is a polarizer (POL)-less structure. In the POL-less structure, the color filter units 152 corresponding to the color of R, G, and B pixels of the OLED film layer are respectively placed, and the black photoresists 151 (such as black matrixes) are filled between the two adjacent color filter units 152. The light emitted by the OLED film layer is transmitted through the color filter units 152. Only the light of the colors corresponding to the color filter units 152 can pass through when the outside sunlight is irradiated onto a surface of the display device, and the sunlight of an non-light-emitting area can be absorbed by the black photoresists 151.

In one embodiment, considering high temperature resistance of an OLED display panel is poor, and the color filter units 152 and the black photoresists 151 are prepared using a low temperature material to avoid damage to the structure within the OLED display panel.

Since an organic solvent is used in a color film layer process, the color filter units 152 and the black photoresists 151 are disposed directly on the thin film encapsulation layer 13. The organic solvent directly infiltrates into the organic encapsulation layers of the thin film encapsulation layer 13, thereby causing organic mutual dissolution to damage a structure of the thin film encapsulation layer 13. The protective effect of the thin film encapsulation layer 13 on the display elements 12 is reduced. Therefore, the present disclosure provides a protective layer 14 between the thin film encapsulation layer 13 and the color film layer 15. It is used to prevent the thin film encapsulation layer 13 from being eroded by the organic solution during a color film layer forming process, thereby improving the stability of the display panel.

In one embodiment, in order to enhance the protective effect of the protective layer 14 on the thin film encapsulation layer 13, two ends of the thin film encapsulation layer 13 are in contact with the substrate 11, and the protective layer 14 covers a boundary of the thin film encapsulation layer 13 and contacts the substrate 11 to complete the coverage of the thin film encapsulation layer 13.

In one embodiment, in order to provide a better barrier effect on the organic solvent, the protective layer 14 is made of an inorganic material. It should be noted that the inorganic materials herein include inorganic materials that are resistant to organic corrosion, such as lithium fluoride.

In one embodiment, in order to enhance the absorption effect of the inorganic material on the organic solution, the inorganic material can be a nano-inorganic material, thereby increasing a surface area of the protective layer 14. In the case of the same volume, the protective layer 14 is made to absorb more organic solvent, thereby reducing the penetration effect of the organic solvent on the thin film encapsulation layer 13.

In one embodiment, the protective layer 14 can also be made of a transparent metal material, and the metal material needs to have high light transmittance, such as indium tin oxide, thereby preventing the protective layer 14 from affecting the display effect of the display panel.

In one embodiment, a refractive index of the protective layer 14 is greater than a refractive index of the thin film encapsulation layer 13 so that the light emitted by the display elements 12 can be collected and emitted at the color filter units 152 to improve the display efficiency of the display panel.

Referring to FIG. 2, a schematic structural view of a protective layer according to an embodiment of the present disclosure is illustrated.

In one embodiment, the protective layer 14 includes at least one first sub-film layer 141 and at least one second sub-film layer 142 stacked on each other, and the first sub-film layer 141 and the second sub-film layer 142 are made of different materials.

In one embodiment, in order to optimize the resistance of the protective layer to the organic solution, the first sub-film layer 141 and the second sub-film layer 142 are prepared by adopting an inorganic material.

In one embodiment, in order to improve the adhesion between the sub-film layers of the protective layer, the first sub-film layer 141 is prepared by adopting an inorganic material, and the second sub-film layer 142 is prepared by adopting an organic material.

According to another aspect of the present disclosure, a display device is also provided. The display device includes a display panel and a frame, wherein the display panel includes a substrate, a plurality of display elements disposed on the substrate, a thin film encapsulation layer disposed on the display elements, a color film layer disposed on the thin film encapsulation layer, and a protective layer disposed between the thin film encapsulation layer, where the color film layer includes a plurality of color filter units corresponding the display elements, respectively, and a plurality of black photoresists disposed within gaps between the adjacent color filter units. The protective layer is configured to protect the thin film encapsulation layer from erosion during a color film layer forming process.

The working principle of the display device is similar to that of the display panel. For details of the working principle of the display device, please refer to the working principle of the display panel, and details are not described herein again.

The present disclosure provides the protective layer between the thin film encapsulation layer and the color film layer. In the color film layer forming process, the organic solvent is prevented from eroding the film encapsulation layer, thereby improving the stability of the display panel.

The present disclosure has been described with preferred embodiments thereof and it is understood that many changes and modifications to the described embodiments can be carried out without departing from the scope and the spirit of the disclosure that is intended to be limited only by the appended claims.

What is claimed is:

1. A display panel, comprising:
a substrate;
a plurality of display elements disposed on the substrate and comprising a first display unit, a second display unit, and a third display unit;
a thin film encapsulation layer disposed on the display elements;
a color film layer disposed on the thin film encapsulation layer and comprising a plurality of color filter units corresponding the display elements, respectively and a plurality of black photoresists disposed within gaps between adjacent color filter units; and
a protective layer disposed between the thin film encapsulation layer and the color film layer and configured to protect the thin film encapsulation layer from erosion during a color film layer forming process;
wherein the first display unit, the second display unit, and the third display unit are one of a red sub-pixel, a green sub-pixel, and a blue sub-pixel, and colors of sub-pixels of the first display unit, the second display unit, and the third display unit are different.

2. The display panel according to claim 1, wherein two ends of the thin film encapsulation layer contact the substrate, and the protective layer covers a boundary of the thin film encapsulation layer and contacts the substrate.

3. The display panel according to claim 1, wherein a preparation material of the protective layer is an inorganic material.

4. The display panel according to claim 3, wherein the inorganic material is a nano-inorganic material.

5. The display panel according to claim 1, wherein the protective layer is prepared by adopting a transparent metal material.

6. The display panel according to claim 1, wherein a refractive index of the protective layer is greater than a refractive index of the thin film encapsulation layer.

7. The display panel according to claim 1, wherein the protective layer comprises at least one first sub-film layer and at least one second sub-film layer stacked on each other, and the first sub-film layer and the second sub-film layer are made of different materials.

8. The display panel according to claim 7, wherein the first sub-film layer and the second sub-film layer are prepared by adopting an inorganic material.

9. The display panel according to claim 7, wherein the first sub-film layer is prepared by adopting an inorganic material, and the second sub-film layer is prepared by adopting an organic material.

10. A display device, comprising a display panel and a frame, wherein the display panel comprises:
a substrate;
a plurality of display elements disposed on the substrate;
a thin film encapsulation layer disposed on the display elements;
a color film layer disposed on the thin film encapsulation layer and comprising a plurality of color filter units corresponding the display elements, respectively, and a plurality of black photoresists disposed within gaps between adjacent color filter units; and
a protective layer disposed between the thin film encapsulation layer and the color film layer and configured to protect the thin film encapsulation layer from erosion during a color film layer forming process.

11. A display panel, comprising:
a substrate;
a plurality of display elements disposed on the substrate;
a thin film encapsulation layer disposed on the display elements;
a color film layer disposed on the thin film encapsulation layer and comprising a plurality of color filter units corresponding the display elements, respectively, and a plurality of black photoresists disposed within gaps between adjacent color filter units; and
a protective layer disposed between the thin film encapsulation layer and the color film layer and configured to protect the thin film encapsulation layer from erosion during a color film layer forming process.

12. The display panel according to claim 11, wherein two ends of the thin film encapsulation layer contact the substrate, and the protective layer covers a boundary of the thin film encapsulation layer and contacts the substrate.

13. The display panel according to claim 11, wherein a preparation material of the protective layer is an inorganic material.

14. The display panel according to claim 13, wherein the inorganic material is a nano-inorganic material.

15. The display panel according to claim 11, wherein the protective layer is prepared by adopting a transparent metal material.

16. The display panel according to claim 11, wherein a refractive index of the protective layer is greater than a refractive index of the thin film encapsulation layer.

17. The display panel according to claim 11, wherein the protective layer comprises at least one first sub-film layer and at least one second sub-film layer stacked on each other, and the first sub-film layer and the second sub-film layer are made of different materials.

18. The display panel according to claim 17, wherein the first sub-film layer and the second sub-film layer are prepared by adopting an inorganic material.

19. The display panel according to claim 17, wherein the first sub-film layer is prepared by adopting an inorganic material, and the second sub-film layer is prepared by adopting an organic material.

20. The display panel according to claim 11, wherein a refractive index of the protective layer is greater than a refractive index of the thin film encapsulation layer.
